(19) United States
(12) Patent Application Publication
(10) Pub. No.: US 2024/0094447 A1
(43) Pub. Date: Mar. 21, 2024

(54) OPTICAL DETECTION DEVICE AND ELECTRONIC APPARATUS

(71) Applicant: SONY SEMICONDUCTOR SOLUTIONS CORPORATION, KANAGAWA (JP)

(72) Inventor: MASAYA MOTOKUBOTA, KANAGAWA (JP)

(21) Appl. No.: 18/264,123

(22) PCT Filed: Dec. 24, 2021
(86) PCT No.: PCT/JP2021/048102

§ 371 Date: Aug. 3, 2023

(30) Foreign Application Priority Data
Feb. 15, 2021 (JP) 2021-021614

(51) Int. Cl. G02B 5/20; H04N 25/13

(52) U.S. Cl. CPC G02B 5/201; H04N 25/134

(57) ABSTRACT

Provided is an optical detection device capable of obtaining an image with higher image quality. The optical detection device includes a plurality of color filters arranged in a two-dimensional array and a substrate including a plurality of photoelectric conversion units on which light passing through the color filters is incident. Then, the optical detection device has a configuration where an angle formed by a light receiving surface of the substrate and color filters (outer color filters) located outside a central portion of the two-dimensional array (color filter array) is different from an angle formed by the light receiving surface of the substrate and a color filter (central portion color filter) located at the central portion such that the outer color filters are inclined toward the central portion relative to the central portion color filter.

### TECHNICAL FIELD

The present disclosure relates to an optical detection device and an electronic apparatus.

### BACKGROUND ART

A color filter of a multilayer film type using a structural color caused by multilayer film interference has been proposed (see, for example, Non-Patent Document 1). In the color filter disclosed in Non-Patent Document 1, a change of the thickness of films constituting the multilayer film causes a change in the wavelength of transmitted light.

### CITATION LIST

### Non-Patent Document

Non-Patent Document 1: Amir Ghobadi, Hodjat Hajian, Murat Gokbayrak, Bayram Butun and Ekmel Ozbay, “Bismuth-based metamaterials: from narrowband reflective color filter to extremely broadband near perfect absorber”, Nanophotonics, Volume 8, Issue 5, id.217, (US), De Gruyter, 2019, p. 655-683

### SUMMARY OF THE INVENTION

### Problems to be Solved by the Invention

For the color filter disclosed in Non-Patent Document 1, however, there has been a possibility that spectral characteristics vary because, when incident light is obliquely incident, an optical path length of the incident light in the multilayer film becomes long. Thus, in a case where the color filter is applied to an optical detection device, there has been a possibility that, for example, on a high image height side where the incident light is obliquely incident, the light is not properly dispersed by the color filter, and a problem such as color mixing occurs. Therefore, there has been a possibility that the image quality of an image obtained by the optical detection device deteriorates.

Furthermore, a similar problem may occur in color filters of other types.

It is therefore an object of the present disclosure to provide an optical detection device and an electronic apparatus capable of obtaining an image with higher image quality.

### Solution to Problems

An optical detection device of the present disclosure includes (a) a plurality of color filters arranged in a two-dimensional array, each of the color filters transmitting light of a predetermined wavelength, and (b) a substrate including a plurality of photoelectric conversion units on which light passing through the color filters is incident, in which (c) an angle formed by a light receiving surface of the substrate and outer color filters that are the color filters located outside a central portion of the two-dimensional array is different from an angle formed by the light receiving surface of the substrate and a central portion color filter that is the color filter located at the central portion such that the outer color filters are inclined toward the central portion relative to the central portion color filter.

An electronic apparatus of the present disclosure includes an optical detection device including (a) a plurality of color filters arranged in a two-dimensional array, each of the color filters transmitting light of a predetermined wavelength, and (b) a substrate including a plurality of photoelectric conversion units on which light passing through the color filters is incident, in which (c) an angle formed by a light receiving surface of the substrate and outer color filters that are the color filters located outside a central portion of the two-dimensional array is different from an angle formed by the light receiving surface of the substrate and a central portion color filter that is the color filter located at the central portion such that the outer color filters are inclined toward the central portion relative to the central portion color filter.

### BRIEF DESCRIPTION OF DRAWINGS

FIG. 1 is a diagram depicting an overall configuration of a solid-state imaging device according to a first embodiment.

FIG. 2 is a diagram depicting a cross-sectional configuration of the solid-state imaging device taken along line A-A in FIG. 1.

FIG. 3 is a diagram depicting a cross-sectional configuration of a multilayer film.

FIG. 4 is a diagram depicting a cross-sectional configuration of a nanostructure.

FIG. 5 is a diagram depicting a cross-sectional configuration of a colored resin film.

FIG. 6 is a diagram depicting a cross-sectional configuration of each part of the solid-state imaging device.

FIG. 7A is a diagram depicting a flow of a color filter layer forming process.

FIG. 7B is a diagram depicting a flow of a color filter layer forming process.

FIG. 8 is a diagram depicting a cross-sectional configuration of each part of a solid-state imaging device according to a second embodiment.

FIG. 9 is a diagram depicting a cross-sectional configuration of each part of a solid-state imaging device according to a modification example.

FIG. 10A is a diagram depicting a flow of a microlens layer forming process.

FIG. 10B is a diagram depicting a flow of a microlens layer forming process.

FIG. 11 is a diagram depicting a cross-sectional configuration of each part of a solid-state imaging device according to a third embodiment.

FIG. 12 is a diagram depicting a cross-sectional configuration of each part of a solid-state imaging device according to a fourth embodiment.

FIG. 13 is a diagram depicting a cross-sectional configuration of a solid-state imaging device according to a modification example.

FIG. 14 is a diagram depicting a cross-sectional configuration of a solid-state imaging device according to a modification example.

FIG. 15 is a diagram depicting a cross-sectional configuration of a solid-state imaging device according to a modification example.

FIG. 16 is a diagram depicting a schematic configuration of an electronic apparatus.

### MODE FOR CARRYING OUT THE INVENTION

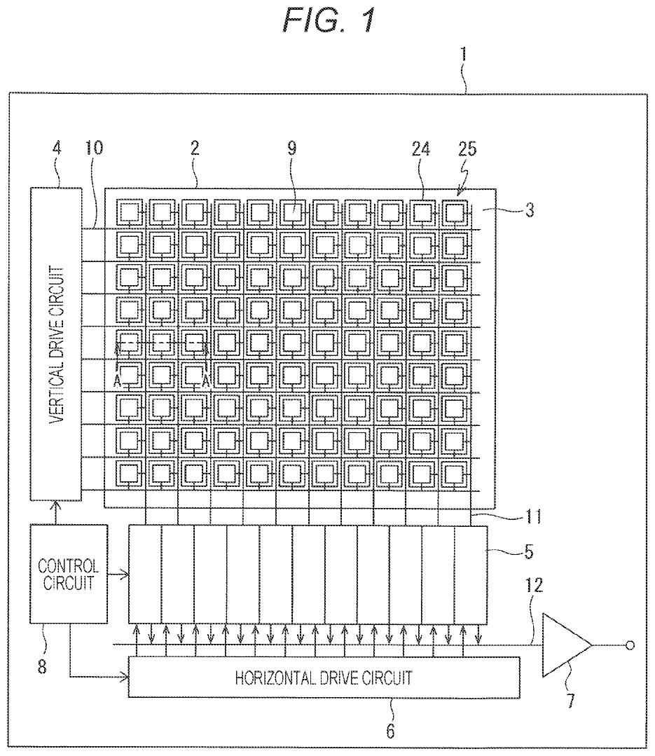

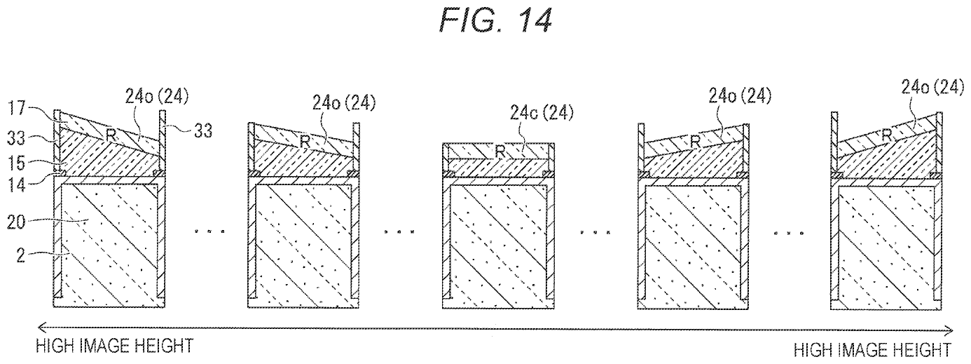

Hereinafter, examples of an optical detection device and an electronic apparatus according to embodiments of the present disclosure will be described with reference to FIGS. 1 to 16. The embodiments of the present disclosure will be described in the following order. Note that the present disclosure is not limited to the following examples. Furthermore, the effects described herein are merely examples and not restrictive, and other effects may be provided.

### 1. First Embodiment: Solid-State Imaging Device

1-1 Overall Configuration of Solid-State Imaging Device
1-2 Configuration of Main Part
1-3 Method for Forming Color Filter Layer

### 2. Second Embodiment: Solid-State Imaging Device

2-1 Configuration of Main Part
2-2 Method for Forming Microlens Layer

### 3. Third Embodiment: Solid-State Imaging Device

### 4. Fourth Embodiment: Solid-State Imaging Device

### 5. Modification Example

### 6. Application Example to Electronic Apparatus

### 1. First Embodiment: Solid-State Imaging Device

### [1-1 Overall Configuration of Solid-State Imaging Device]

A solid-state imaging device 1 (in a broad sense, an “optical detection device”) according to a first embodiment of the present disclosure will be described. FIG. 1 is a schematic configuration diagram depicting the entire solid-state imaging device 1 according to the first embodiment.

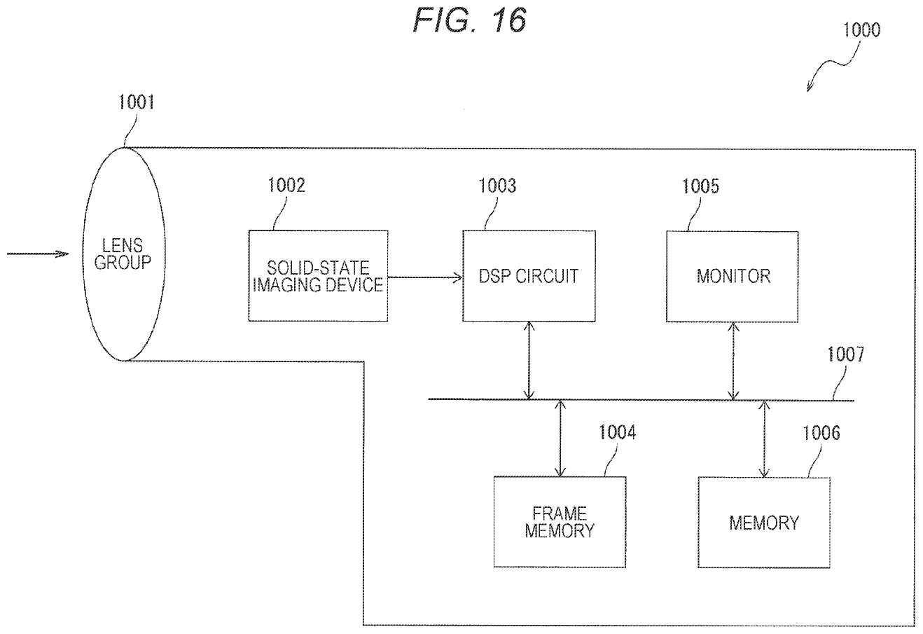

The solid-state imaging device 1 in FIG. 1 is a back-illuminated complementary metal oxide semiconductor (CMOS) image sensor. As depicted in FIG. 16, the solid-state imaging device 1 (1002) captures image light (incident light) from a subject through a lens group 1001, converts an amount of the incident light formed as an image on an imaging surface into an electrical signal for each pixel, and outputs the electrical signal as a pixel signal.

As depicted in FIG. 1, the solid-state imaging device 1 includes a substrate 2, a pixel region 3, a vertical drive circuit 4, a column signal processing circuit 5, a horizontal drive circuit 6, an output circuit 7, and a control circuit 8.

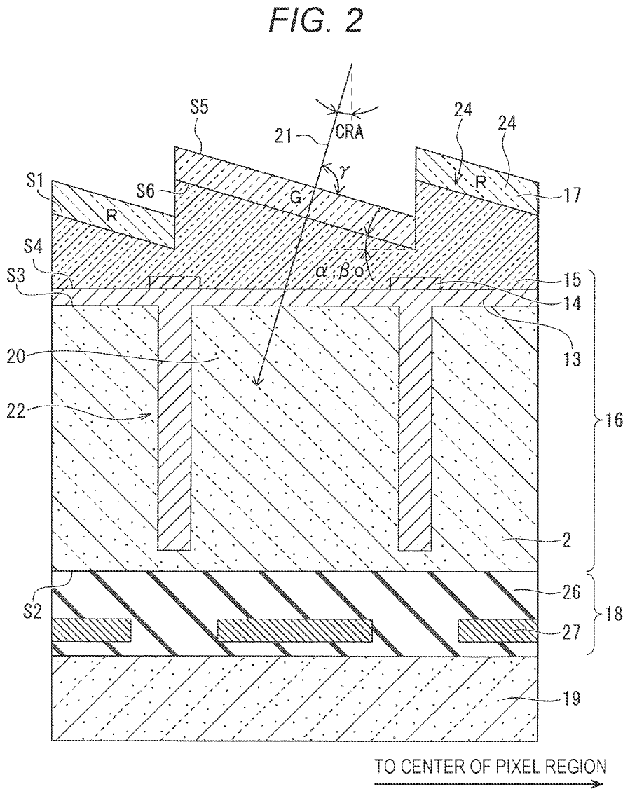

The pixel region 3 has a plurality of pixels 9 regularly arranged in a two-dimensional array on the substrate 2. Each pixel 9 includes a photoelectric conversion unit 20 depicted in FIG. 2 and a plurality of pixel transistors (not illustrated). As the plurality of pixel transistors, for example, four transistors of a transfer transistor, a reset transistor, a selection transistor, and an amplification transistor may be employed. Furthermore, for example, three transistors excluding the selection transistor may be employed.

The vertical drive circuit 4 includes, for example, a shift register, selects a desired pixel drive wiring 10, supplies a pulse for driving the pixels 9 to the selected pixel drive wiring 10, and drives each pixel 9 on a row basis. That is, the vertical drive circuit 4 selectively scans each pixel 9 in the pixel region 3 sequentially in a vertical direction on a row basis, and supplies a pixel signal based on a signal charge generated in accordance with an amount of received light in the photoelectric conversion unit 20 of each pixel 9, to the column signal processing circuit 5 through a vertical signal line 11.

The column signal processing circuit 5 is arranged, for example, for each column of the pixels 9, and performs signal processing such as noise removal on signals output from the pixels 9 of one row for each pixel column. For example, the column signal processing circuit 5 performs signal processing such as correlated double sampling (CDS) for removing a pixel-specific fixed pattern noise, and analog digital (AD) conversion.

The horizontal drive circuit 6 includes, for example, a shift register, sequentially outputs horizontal scanning pulses to the column signal processing circuits 5, sequentially selects each of the column signal processing circuits 5, and causes each of the column signal processing circuits 5 to output the pixel signal subjected to the signal processing, to a horizontal signal line 12.

The output circuit 7 performs signal processing on the pixel signals sequentially supplied from each of the column signal processing circuits 5 through the horizontal signal line 12 and outputs processed signals. As the signal processing, for example, buffering, black level adjustment, column variation correction, various kinds of digital signal processing, and the like may be used.

The control circuit 8 generates, on the basis of a vertical synchronization signal, a horizontal synchronization signal, and a master clock signal, a clock signal or a control signal in accordance with which the vertical drive circuit 4, the column signal processing circuits 5, the horizontal drive circuit 6, and the like operate. Then, the control circuit 8 outputs the clock signal or control signal thus generated to the vertical drive circuit 4, the column signal processing circuits 5, the horizontal drive circuit 6, and the like.

### [1-2 Configuration of Main Part]

Next, a detailed structure of the solid-state imaging device 1 in FIG. 1 will be described. FIG. 2 is a diagram depicting a cross-sectional configuration of the solid-state imaging device 1 taken along line A-A in FIG. 1.

As depicted in FIG. 2, the solid-state imaging device 1 includes a light receiving layer 16, the light receiving layer 16 including the substrate 2, an insulating film 13, a light shielding film 14, and an insulating film 15 stacked in this order. Furthermore, a color filter layer 17 is formed on a surface of the light receiving layer 16 on the insulating film 15 side (hereinafter, also referred to as a “back surface Si”). Note that an antireflection film (ARC) may be stacked on a back surface S5 of the color filter layer 17. Moreover, a wiring layer 18 and a support substrate 19 are stacked in this order on a surface of the light receiving layer 16 on the substrate 2 side (hereinafter, also referred to as a “front surface S2”). Note that, in the following description, the back surface of the insulating film 15 is also referred to as the “back surface Si”. Furthermore, the front surface of the substrate 2 is also referred to as the “front surface S2”.

The substrate 2 includes a semiconductor substrate containing, for example, silicon (Si), and is formed with the pixel region 3. In the pixel region 3, the plurality of pixels 9 each including the photoelectric conversion unit 20 is arranged in a two-dimensional array. Each photoelectric conversion unit 20 is buried in the substrate 2 to constitute a photodiode, generates a signal charge corresponding to an amount of incident light 21, and accumulates the generated signal charge.

Furthermore, each photoelectric conversion unit 20 is physically isolated by a pixel isolation part 22. The pixel isolation part 22 is formed in a lattice shape so as to surround each photoelectric conversion unit 20. Furthermore, the insulating film 13 covering a back surface S3 side of the substrate 2 is buried inside the pixel isolation part 22.

The insulating film 13 continuously covers the entire back surface S3 side (entire light receiving surface side) of the substrate 2 and the inside of the pixel isolation part 22. As a material of the insulating film 13, for example, an insulator or the like may be used. Specifically, silicon oxide (SiO₂) or silicon nitride (SiN) may be employed. Furthermore, the light shielding film 14 is formed in a lattice shape that opens the light receiving surface side of each of the plurality of photoelectric conversion units 20, on a back surface S4 side of the insulating film 13 so as to prevent light from leaking into adjacent pixels 9. Furthermore, the insulating film 15 continuously covers the entire back surface S4 side of the insulating film 13 including the light shielding film 14 such that the back surface S1 of the light receiving layer 16 has an uneven structure 23 having a plurality of inclined surfaces that each support a corresponding one of the color filters 24 at a suitable angle. As a material of the insulating film 15, for example, silicon oxide (SiO₂), silicon nitride (SiN), or the like may be employed, in a manner similar to the material of the insulating film 13.

The color filter layer 17 is formed on the back surface S1 side of the insulating film 15 and includes the plurality of color filters 24 arranged corresponding to the respective pixels 9. That is, the plurality of color filters 24 is arranged in a two-dimensional array to form a color filter array 25 (see FIG. 1). Furthermore, the plurality of color filters 24 includes a plurality of types of color filters that transmit light of different wavelengths (for example, red light, green light, and blue light). With this configuration, each of the plurality of color filters 24 transmits light of a wavelength predetermined for each type of the color filters 24, and causes the transmitted light to enter photoelectric conversion unit 20. As an array pattern of the color filters 24, for example, a Bayer array may be employed. Furthermore, the color filters 24 have a flat plate shape with the back surface S5 and a front surface S6 flat and parallel to each other.

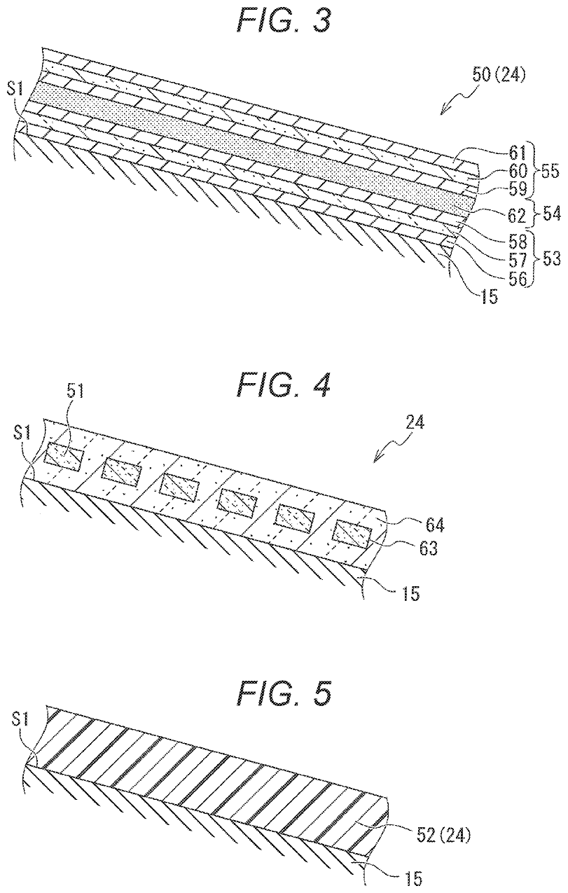

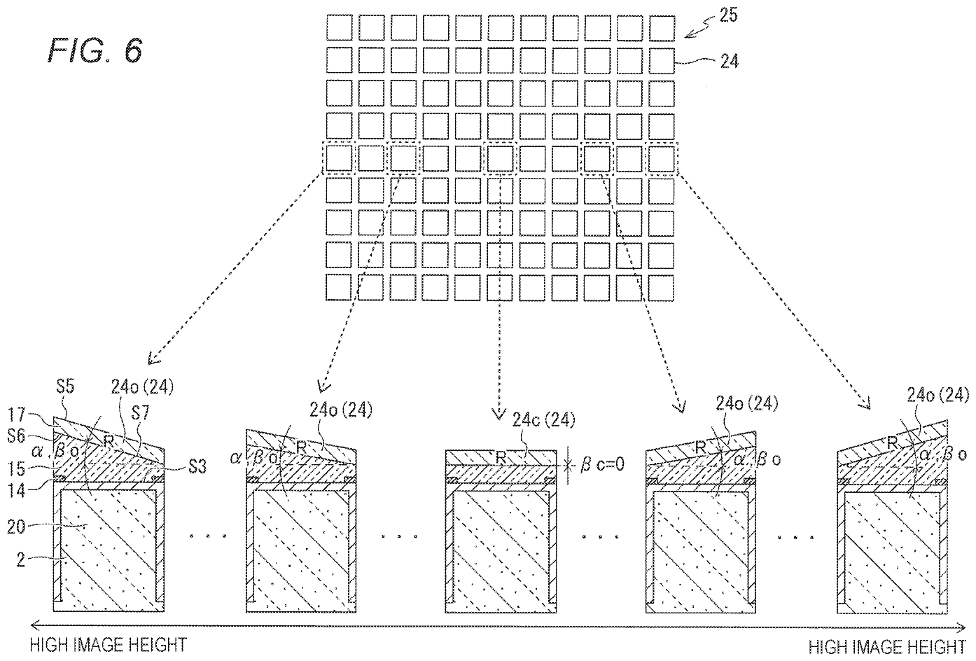

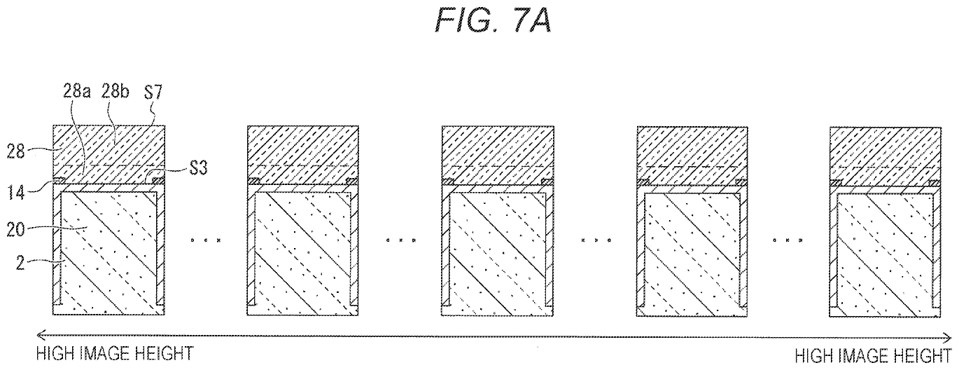

Examples of each color filter 24 include one of a filter including a multilayer film 50 (see FIG. 3) having a low refractive index layer and a high refractive index layer alternately stacked, a filter including a plurality of nanostructures 51 (see FIG. 4) smaller than a wavelength of light the color filters 24 transmit, or a colored resin film 52 (see FIG. 5) containing a resin material having a colorant dispersed therein, and a combination thereof. Examples of the filter including the multilayer film 50 include a structural color filter using multilayer film interference (in other words, a photonic liquid crystal filter, a filter including a dielectric multilayer film). As depicted in FIG. 3, the multilayer film 50 including a lower mirror layer 53, a control layer 54, and an upper mirror layer 55 stacked in this order on the back surface S1 of the insulating film 15. The lower mirror layer 53 includes a high refractive index layer 56, a low refractive index layer 57, and a high refractive index layer 58 stacked in this order from the back surface S1 side of the insulating film 15. Furthermore, the upper mirror layer 55 includes a high refractive index layer 59, a low refractive index layer 60, and a high refractive index layer 61 stacked in this order from the control layer 54 side. With this configuration, the lower mirror layer 53 and the upper mirror layer 55 function as mirrors having their respective reflection surfaces facing each other.

Furthermore, the control layer 54 includes a low refractive index layer 62, and causes interference of light multiple-reflected by the respective reflection surfaces of the lower mirror layer 53 and the upper mirror layer 55. With this configuration, a change of a film thickness of the control layer 54 allows the multilayer film 50 to serve as color filters 24 that transmit light of different wavelengths (in other words, color filters 24 adapted to different peak wavelength positions of transmitted light, color filters 24 having different spectral characteristics). As a material of the low refractive index layers 57, 62, and 60, a low refractive index material (for example, silicon oxide (SiO₂, refractive index 1.45)) may be employed. Furthermore, as a material of the high refractive index layers 56, 58, 59, and 61, a high refractive index material (for example, titanium oxide (TiO₂, refractive index 2.5)) higher in refractive index than the low refractive index layers 57, 62, and 60 may be employed. This configuration prevents the multilayer film 50 from properly dispersing light when the incident light 21 is obliquely incident to make the optical path length of the incident light 21 in the control layer 54 longer than the film thickness of the control layer 54.

Furthermore, examples of the filter including the plurality of nanostructures 51 include a structural color filter (metamaterial filter) using guided mode resonance or surface plasmon resonance. As depicted in FIG. 4, the structural color filter using the guided mode resonance includes a guided mode resonance grating 63 having a diffraction grating and an insulating layer 64 covering the guided mode resonance grating 63. In the guided mode resonance grating 63, each linear portion constituting the diffraction grating is a nanostructure 51 having a line width smaller than the wavelength of light the color filters 24 transmit. Furthermore, the guided mode resonance grating 63 includes a high refractive material layer. Furthermore, the insulating layer 64 includes a low refractive index material layer lower in refractive index than the high refractive material layer. With this configuration, a change of a pattern period of the diffraction grating allows the nanostructures 51 to serve as color filters 24 that transmit light of different wavelengths (in other words, color filters 24 adapted to different peak wavelength positions of transmitted light, color filters 24 having different spectral characteristics). As a material of the low refractive material layer, for example, silicon oxide (SiO₂, refractive index 1.45) may be employed. As a material of the high refractive material layer, a material higher in refractive index than the low refractive material layer may be employed. Examples of the material include silicon (Si, refractive index 3.42). This configuration prevents the nanostructures 51 from properly dispersing light when the incident light 21 is obliquely incident to make the pattern period of the diffraction grating when viewed from the direction along the incident direction smaller.

Furthermore, examples of the filter including the colored resin film 52 include a filter including a color resist. The colorant contained in the colored resin film 52 includes a pigment or a dye, transmits light of a predetermined wavelength (for example, red light), and absorbs light of other wavelengths (for example, green light and blue light). With this configuration, a change of the colorant allows the colored resin film 52 to serve as color filters 24 that transmit light of different wavelengths (in other words, color filters 24 adapted to different peak wavelength positions of transmitted light, color filters 24 having different spectral characteristics). Such a configuration prevents the colored resin film 52 from properly dispersing light when the incident light 21 is obliquely incident to make the optical path length of the incident light 21 in the colored resin film 52 longer than the film thickness of the colored resin film 52.

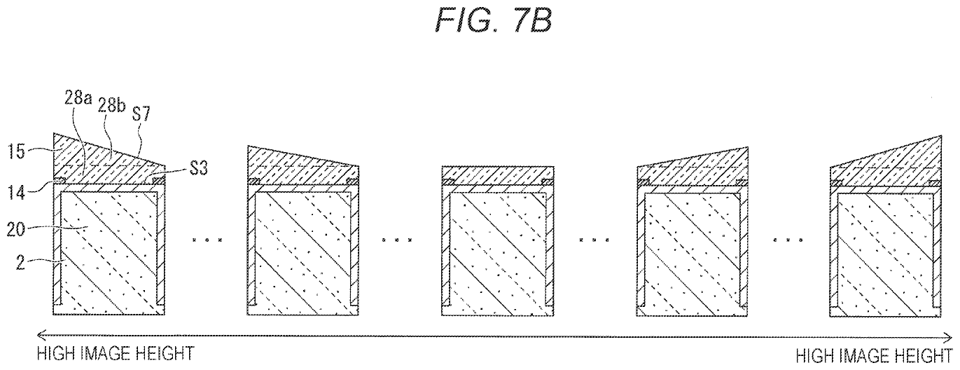

Furthermore, as depicted in FIG. 6, a color filter 24 located at a central portion of the color filter array 25 (hereinafter, also referred to as a “central portion color filter 24c”) is arranged so as to make the back surface S5 (light receiving surface) parallel to the back surface S3 (light receiving surface) of the substrate 2. As the central portion color filter 24c, for example, one color filter 24 at the center of the color filter array 25, four color filters 24 arranged in a Bayer array at the center of the color filter array 25, and a plurality of color filters 24 within a predetermined distance from the central portion of the color filter array 25 may be employed.

Furthermore, a color filter 24 located outside the central portion of the color filter array 25 (hereinafter, also referred to as an “outer color filter 24o”) is arranged so as to cause the back surface S5 (light receiving surface) to face the central portion side. In other words, it can be said that the outer color filter 24o is inclined toward the central portion of the color filter array 25 relative to the central portion color filter 24c. An angle γ formed by the incident light 21 that is obliquely incident and the back surface S5 (light receiving surface) of the color filter 24 can be brought close to 90° on end portion sides (high image height sides) of the pixel region 3 by a relative inclination angle α of the outer color filter 24o relative to the central portion color filter 24c, and it is thus possible to prevent the characteristics of the color filter 24 from deteriorating due to the oblique incidence of the incident light 21. It is therefore possible for the color filter 24 to properly disperse light and suppress the occurrence of a problem such as color mixing. FIG. 6 illustrates a case where an angle formed by the front surface S6 (surface adjacent to the insulating film 15) of the central portion color filter 24c and the front surface S6 (surface adjacent to the insulating film 15) of the outer color filter 24o is “α”.

Note that, in the first embodiment, the back surface S3 (light receiving surface) of the substrate 2 is a flat surface, and an angle βc formed by the back surface S3 (light receiving surface) of the substrate 2 and the central portion color filter 24c is 0°, so that the relative inclination angle α of the outer color filter 24o relative to the central portion color filter 24c and an angle βo formed by the back surface S3 (light receiving surface) of the substrate 2 and the outer color filter 24o are the same (α=βo). Thus, it can be said that the angle (3o formed by the back surface S3 (light receiving surface) of the substrate 2 and the outer color filter 24o is different from the angle βc formed by the back surface S3 (light receiving surface) of the substrate 2 and the central portion color filter 24c. Therefore, in the solid-state imaging device 1 according to the first embodiment, it can be said that the angle βo formed by the back surface S3 (light receiving surface) of the substrate 2 and the outer color filter 24o is different from the angle βc formed by the back surface S3 (light receiving surface) of the substrate 2 and the central portion color filter 24c such that the outer color filter 24o is inclined toward the central portion of the color filter array 25 relative to the central portion color filter 24c. FIG. 6 illustrates a case where the angle formed by the front surface S6 (surface adjacent to the insulating film 15) of the central portion color filter 24c and the back surface S3 of the substrate 2 (specifically, the back surface S3 of the substrate 2 at a position where the photoelectric conversion unit 20 corresponding to the central portion color filter 24c is located) is “βc”. Furthermore, a case where the angle formed by the front surface S6 (surface adjacent to the insulating film 15) of the outer color filter 24c and the back surface S3 of the substrate 2 (specifically, the back surface S3 of the substrate 2 at a position where the photoelectric conversion unit 20 corresponding to the outer color filter 24o is located) is “βo” is illustrated.

Furthermore, the relative inclination angle α of the outer color filter 24o relative to the central portion color filter 24c (hereinafter, also referred to as an “inclination angle α of the outer color filter 24o”) is preferably set, for each outer color filter 24o, equal to a chief ray angle (CRA) at the pixel 9 corresponding to the outer color filter 24o, for example (α=CRA . . . (1)). It is possible to prevent, by setting α=CRA to make the incident light 21 perpendicularly incident on the back surface S5 (light receiving surface) of the color filter 24, a problem such as color mixing from occurring even if the color filter 24 is poor in oblique incidence characteristics. In a case where the inclination angle α of each outer color filter 24o is α=CRA, the farther away from the central portion of the color filter array 25, the larger the chief ray angle CRA, and thus the larger the inclination angle α of the outer color filter 24o. In other words, it can be said that the relative inclination angle α of the outer color filter 24o located remote from the central portion of the color filter array 25 relative to the central portion color filter 24c is larger than the relative inclination angle α of the outer color filter 24o located adjacent to the central portion.

The wiring layer 18 is formed on the front surface S2 side of the substrate 2, and includes an interlayer insulating film 26 and a plurality of layers of wirings 27 stacked with the interlayer insulating film 26 interposed therebetween. Then, the wiring layer 18 drives the pixel transistors constituting each pixel 9 via the plurality of layers of wirings 27.

The support substrate 19 is formed on a surface of the wiring layer 18 remote from the substrate 2. The support substrate 19 is a substrate for securing strength of the substrate 2 at a manufacturing stage of the solid-state imaging device 1. As a material of the support substrate 19, for example, silicon (Si) may be used.

In the solid-state imaging device 1 having the above-described configuration, image light (incident light 21) is applied to the back surface S5 side of the color filter 24, light in a predetermined wavelength region of the incident light 21 thus applied passes through the color filter 24 and is photoelectrically converted by the photoelectric conversion unit 20 into a signal charge. Then, the generated signal charge is output as a pixel signal through the vertical signal line 11 depicted in FIG. 1, the vertical signal line 11 being formed by the wirings 27, via the pixel transistors formed on the front surface S2 side of the substrate 2.

### [1-3 Method for Forming Color Filter Layer]

Next, a method for forming the color filter layer 17 in the solid-state imaging device 1 will be described.

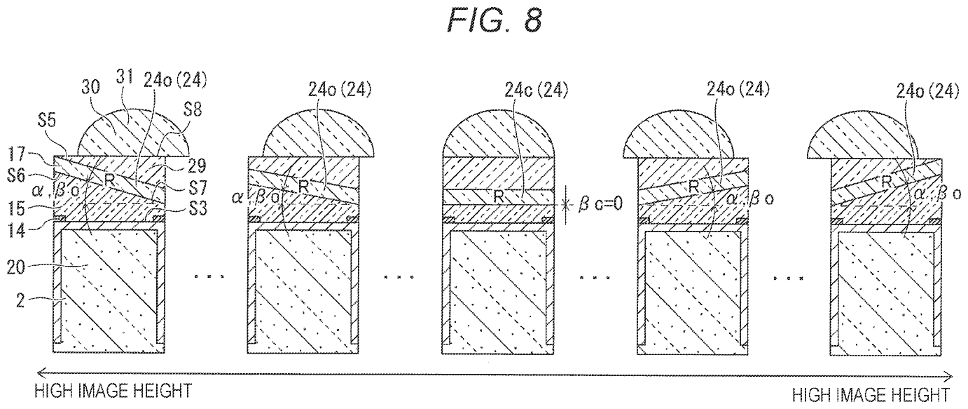

First, as depicted in FIG. 7A, a first material film 28 including the material of the insulating film 15 is formed on the back surface S3 (light receiving surface) of the substrate 2. The first material film 28 may have a two-layer configuration of a first layer 28a continuously covering the substrate 2 and the light shielding film 14 and a second layer 28b formed on the light receiving surface side of the first layer 28a. Furthermore, the first layer 28a and the second layer 28b may include the same material or different materials. A back surface S7 of the first material film 28 is a flat surface parallel to the back surface S3 (light receiving surface) of the substrate 2. Subsequently, the first material film 28 is etched back from the back surface S7 side by a grayscale lithography technique to form the insulating film 15 having the uneven structure 23 on the back surface S7 as depicted in FIG. 7B. In the uneven structure 23, the region where the central portion color filter 24c is formed is entirely a flat surface parallel to the back surface S3 (light receiving surface) of the substrate 2, and each region where the outer color filter 24o is formed is an inclined surface inclined toward the central portion.

Subsequently, as depicted in FIG. 6, a plurality of flat color filters 24 is formed on the back surface S7 of the insulating film 15. Accordingly, the back surface S5 (light receiving surface) of the central portion color filter 24c of the plurality of color filters 24 becomes parallel to the back surface S3 (light receiving surface) of the substrate 2. Furthermore, the back surface S5 (light receiving surface) of the outer color filter 24o is inclined toward the central portion of the color filter array 25. With this configuration, the color filter layer 17 is obtained in which the inclination of the outer color filter 24o relative to the back surface S3 (light receiving surface) of the substrate 2 is different from the inclination of the central portion color filter 24c relative to the back surface S3 (light receiving surface) of the substrate 2 such that the outer color filter 24o is inclined toward the central portion relative to the central portion color filter 24c.

As described above, in the solid-state imaging device 1 according to the first embodiment, the angle 3o formed by the back surface S3 (light receiving surface) of the substrate 2 and the color filter 24 (outer color filter 24o) located outside the central portion of the color filter array 25 (two-dimensional array) is different from the angle 3c formed by the back surface S3 (light receiving surface) of the substrate 2 and the color filter 24 (central portion color filter 24c) located at the central portion such that the outer color filter 24o is inclined toward the central portion relative to the central portion color filter 24c. Therefore, on the end portion sides (high image height sides) of the pixel region 3, the angle γ formed by the incident light 21 that is obliquely incident and the back surface S5 (light receiving surface) of the color filter 24 can be brought close to 90°, and it is thus possible to prevent the characteristics of the color filter 24 from deteriorating due to the oblique incidence of the incident light 21. It is therefore possible for the color filter 24 to disperse light more properly and suppress the occurrence of a problem such as color mixing. It is therefore possible to provide the solid-state imaging device 1 capable of obtaining an image with higher image quality.

Furthermore, since the angle γ formed by the incident light 21 and the back surface S5 (light receiving surface) of the color filter 24 can be brought close to 90°, it is possible to open a way to employ, as the color filter 24, a filter having a new material and a new structure with poor oblique incidence characteristics, such as a filter including the multilayer film 50 or a filter including the plurality of nanostructures 51. Then, the use of the filter having a new material and a new structure allows the color filter 24 to have, for example, a light condensing function like a microlens, and allows a reduction in the height of the solid-state imaging device 1 as compared with a case where the color filter 24 and the microlens are separately formed. Furthermore, for example, a full width at half maximum of the color filter 24 can be narrowed, and a multispectral sensor having a narrow full width at half maximum can be realized.

### 2. Second Embodiment: Solid-State Imaging Device

### [2-1 Configuration of Main Part]

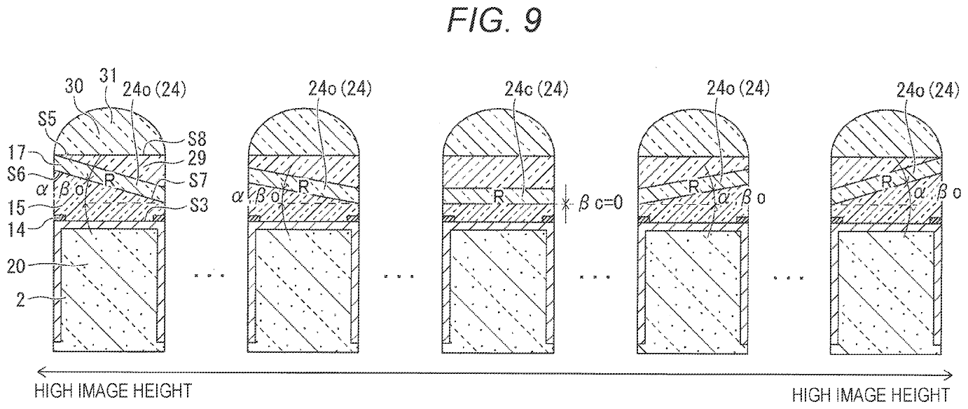

Next, a solid-state imaging device 1 according to a second embodiment of the present disclosure will be described. An overall configuration of the solid-state imaging device 1 according to the second embodiment is similar to that in FIG. 1, and thus illustration thereof will be omitted. FIG. 8 is a diagram depicting a cross-sectional configuration of the solid-state imaging device 1 according to the second embodiment. In FIG. 8, portions corresponding to those in FIG. 6 are denoted by the same reference numerals, and redundant description will be omitted.

As depicted in FIG. 8, the solid-state imaging device 1 according to the second embodiment is different from the solid-state imaging device 1 according to the first embodiment in that a lens base layer 29 and a microlens layer 30 are stacked in this order on the back surface S5 side (light receiving surface side) of the color filter layer 17.

The lens base layer 29 continuously covers the entire back surface S5 side of the color filter 24 so as to make a back surface S8 of the lens base layer 29 flat without unevenness. As a material of the lens base layer 29, for example, a material almost identical in refractive index to the material of the microlens 31 may be employed. Examples of the material include silicon oxide (SiO₂) and silicon nitride (SiN).

The microlens layer 30 includes a plurality of the microlenses 31 arranged corresponding to the respective pixels 9. That is, the plurality of microlenses 31 is arranged in a two-dimensional array to form a microlens array. With this configuration, each of the plurality of microlenses 31 concentrates the incident light 21 into the photoelectric conversion unit 20 through the color filter 24. At this time, the color filter 24 transmits light of a predetermined wavelength (red light, green light, or blue light) included in the incident light 21 concentrated by the microlens 31 corresponding to the color filter 24.

Furthermore, each of the microlenses 31 is arranged at a position subjected to pupil correction. That is, as closer to the end portion sides of the pixel region 3, a central portion of the microlens 31 in plan view is shifted toward a central portion of the pixel region 3 relative to the center of the photoelectric conversion unit 20 corresponding to the microlens 31. It is possible to suppress, with the arrangement at the position subjected to pupil correction, the occurrence of vignetting in which the incident light 21 is blocked by the light shielding film 14 on the end portion sides (high image height sides) of the pixel region 3 and make the incident light 21 incident on the photoelectric conversion unit 20 more properly, which allows an increase in the sensitivity of the pixel 9.

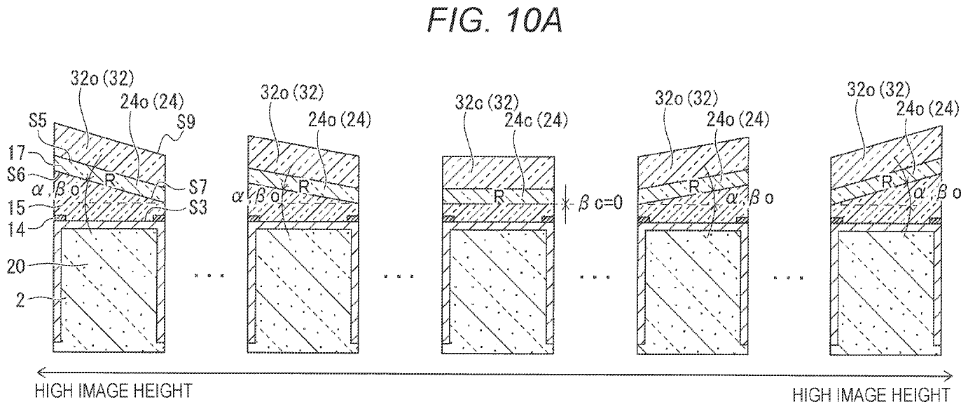

Note that, although the case where the microlens 31 is arranged at the position subjected to pupil correction has been given as an example, the position of the microlens 31 need not be subjected to pupil correction as illustrated in FIG. 9, for example.

Furthermore, in the second embodiment, the relative inclination angle α of the outer color filter 24o relative to the central portion color filter 24c (the inclination angle α of the outer color filter 24o) is an angle expressed by the following expression (2). In the following expression (2), the inclination angle α of the outer color filter 24o is set using the chief ray angle CRA and a refractive index n of the microlens 31. That is, the following expression (2) is an expression based on the above-described expression (1) with consideration given to the influence of refraction of light that occurs at the interface between the air and the microlens 31. It is possible to prevent, by setting the inclination angle α of the outer color filter 24o using the following expression (2) to make the incident light 21 refracted off the interface between the air and the microlens 31 perpendicularly incident on the back surface S5 (light receiving surface) of the outer color filter 24o, a problem such as color mixing from occurring even if the outer color filter 24o is poor in oblique incidence characteristics.

α=arcsin(sin(CRA)/n) (2)

Note that the above-described expression (2) can also be applied to a case where a structure other than the microlens 31 is located immediately above the color filter 24. In this case, a refractive index of the structure is used as the refractive index n.

### [2-2 Method for Forming Microlens Layer]

Next, a method of forming the microlens layer 30 in the solid-state imaging device 1 will be described.

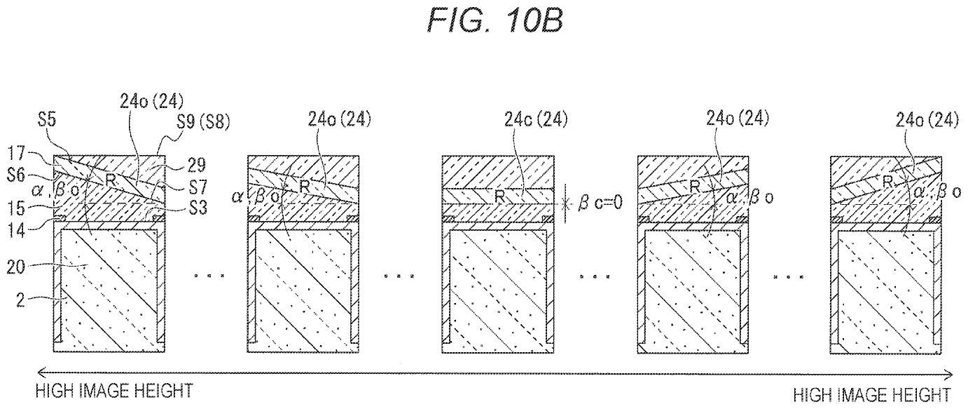

First, the color filter layer 17 is formed by a procedure similar to the procedure in FIGS. 7A, 7B, and 6 described above. Subsequently, as depicted in FIG. 10A, a second material film 32 including the material of the lens base layer 29 and having a uniform thickness is formed on the back surface S5 (light receiving surface) of the color filter layer 17. Accordingly, a portion 32c of the second material film 32 formed on the back surface S5 of the central portion color filter 24c is parallel to the back surface S3 (light receiving surface) of the substrate 2. Furthermore, a portion 32o formed on the back surface S5 of the outer color filter 24o is inclined toward the central portion.

Subsequently, the second material film 32 is polished from a back surface S9 side by a chemical mechanical polishing (CMP) technique to form the lens base layer 29 having the flat back surface S8 as depicted in FIG. 10B. Subsequently, as depicted in FIG. 8, the plurality of microlenses 31 is formed on the back surface S8 of the lens base layer 29. As a result, the microlens layer 30 is obtained.

### 3. Third Embodiment: Solid-State Imaging Device

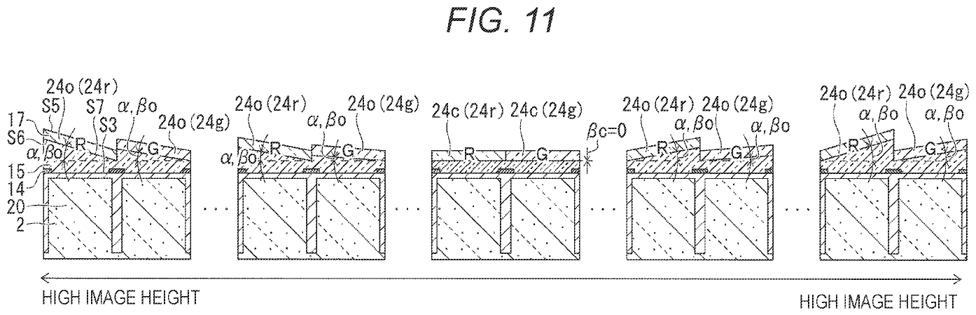

Next, a solid-state imaging device 1 according to a third embodiment of the present disclosure will be described. An overall configuration of the solid-state imaging device 1 according to the third embodiment is similar to that in FIG. 1, and thus illustration thereof will be omitted. FIG. 11 is a diagram depicting a cross-sectional configuration of the solid-state imaging device 1 according to the third embodiment. In FIG. 11, portions corresponding to those in FIG. 6 are denoted by the same reference numerals, and redundant description will be omitted.

As depicted in FIG. 11, the solid-state imaging device 1 according to the third embodiment is different from the solid-state imaging device 1 according to the first embodiment in that, for each of the outer color filters 24o having the same spectral characteristics, the relative inclination angle α of the outer color filter 24o located remote from the central portion of the color filter array 25 is larger than the relative inclination angle α of the outer color filter 24o located adjacent to the central portion. FIG. 11 depicts a cross section of a color filter 24 having such spectral characteristics as to transmit red light (hereinafter, also referred to as “red filter 24r”) and a cross section of a color filter 24 having such spectral characteristics as to transmit green light (hereinafter, also referred to as “green filter 24g”).

In the third embodiment, the relative inclination angle α of the outer color filter 24o relative to the central portion color filter 24c (the inclination angle α of the outer color filter 24o) is an angle expressed by the following expression (3). In the following expression (3), the inclination angle α of the outer color filter 24o is set using the chief ray angle CRA and a correction coefficient k set for each color filter 24 having the same spectral characteristics. That is, the following expression (3) is an expression based on the above-described expression (1) with consideration given to angle response characteristics and oblique incidence characteristics for each color filter 24.

α=arcsin(sin(CRA))×k (3)

Setting the inclination angle α of the outer color filter 24o is set using the above-described expression (3) makes the inclination angle α of the outer color filter 24o become larger for each red filter 24r and each green filter 24g because the farther away from the central portion of the color filter array 25, the larger the chief ray angle CRA. In other words, for each outer color filter 24o having the same spectral characteristics, it can be said that the relative inclination angle α, relative to the central portion color filter 24c, of the outer color filter 24o located remote from the central portion of the color filter array 25 is larger than the relative inclination angle α of the outer color filter 24o located adjacent to the central portion.

Note that such a relationship (relative inclination angle α of outer color filter 24o located remote from the central portion of color filter array 25>relative inclination angle α of outer color filter 24o located adjacent to the central portion) is not necessarily satisfied between outer color filters 24o having different spectral characteristics. FIG. 11 illustrates a case where there is a portion (portion on the right side of FIG. 11) where the inclination angle α of the green filter 24g located remote from the central portion of the color filter array 25<the inclination angle α of the red filter 24r located adjacent to the central portion.

Furthermore, although the case where the microlens 31 is not provided on the back surface S5 side (light receiving surface side) of the color filter 24 has been given as an example, in a case where the microlens 31 is provided, for example, as illustrated in FIGS. 8 and 9, the inclination angle α of the outer color filter 24o is expressed by the following expression (4).

α=arcsin(sin(CRA)/n)×k (4)

### 4. Fourth Embodiment: Solid-State Imaging Device

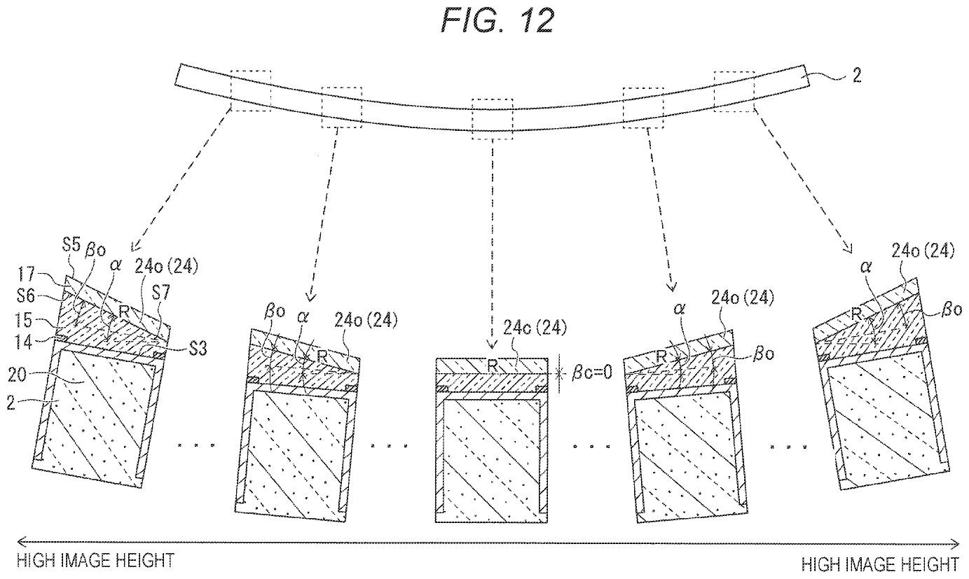

Next, a solid-state imaging device 1 according to a fourth embodiment of the present disclosure will be described. An overall configuration of the solid-state imaging device 1 according to the fourth embodiment is similar to that in FIG. 1, and thus illustration thereof will be omitted. FIG. 12 is a diagram depicting a cross-sectional configuration of the solid-state imaging device 1 according to the fourth embodiment. In FIG. 12, portions corresponding to those in FIG. 6 are denoted by the same reference numerals, and redundant description will be omitted.

As depicted in FIG. 12, the solid-state imaging device 1 according to the fourth embodiment is different from the solid-state imaging device 1 according to the first embodiment in that the central portion of the substrate 2 serves as a curved sensor that is curved toward the wiring layer 18 (that is, toward a side remote from the color filter 24). As the shape of the curve at the central portion of the substrate 2, in a case of a configuration where a camera module includes the solid-state imaging device 1 and an imaging lens arranged on the solid-state imaging device 1, for example, a curved surface shape that matches the curvature of a surface where an image of a subject is formed by the imaging lens may be employed. It is possible to prevent, by curving the central portion of the substrate 2 toward the side remote from the color filter 24, the end portion sides (high image height sides) of the pixel region 3 from being out of focus due to field curvature aberration and allows the end portion sides to have resolution equivalent to resolution of the central portion side of the pixel region 3.

Furthermore, as in the first embodiment, the outer color filter 24o is inclined toward the central portion of the color filter array 25 relative to the central portion color filter 24c. Furthermore, although the substrate 2 is curved, also in the fourth embodiment, each of the outer color filters 24o is inclined toward the center of the color filter array 25 relative to the back surface S3 (light receiving surface) of the substrate 2. That is, the angle βo formed by the back surface S3 (light receiving surface) of the substrate 2 and the outer color filter 24o satisfies βo>0. Therefore, also in the solid-state imaging device 1 according to the fourth embodiment, it can be said that the angle βo formed by the back surface S3 (light receiving surface) of the substrate 2 and the outer color filter 24o is different from the angle βc formed by the back surface S3 (light receiving surface) of the substrate 2 and the central portion color filter 24c such that the outer color filter 24o is inclined toward the central portion of the color filter array 25 relative to the central portion color filter 24c. FIG. 12 illustrates a case where the angle formed by the front surface S6 (surface adjacent to the insulating film 15) of the central portion color filter 24c and the back surface S3 of the substrate 2 (specifically, the back surface S3 of the substrate 2 at a position where the photoelectric conversion unit 20 corresponding to the central portion color filter 24c is located) is “βc”. Furthermore, a case where the angle formed by the front surface S6 (surface adjacent to the insulating film 15) of the outer color filter 24c and the back surface S3 of the substrate 2 (specifically, the back surface S3 of the substrate 2 at a position where the photoelectric conversion unit 20 corresponding to the outer color filter 24o is located) is “βo” is illustrated.

### 5. Modification Example

(1) Note that, in the first to fourth embodiments, the example where the farther away from the central portion of the color filter array 25, the larger the relative inclination angle α of the outer color filter 24o relative to the central portion color filter 24c (the inclination angle α of the outer color filter 24o) has been described, but other configurations may be employed. That is, the example where the inclination angle α is individually set for each of the outer color filters 24o has been described, but other configurations may be employed. For example, a configuration where the color filter array 25 is divided into a plurality of regions in accordance with the distance from the central portion, the inclination angle α of the outer color filter 24o is set at a fixed value for each region obtained by the division, and the farther the region is away from the central portion, the larger the fixed value may be employed. That is, a configuration where the inclination angle α is set for each region may be employed.

(2) Furthermore, in the first to fourth embodiments, the example where all of the outer color filters 24o satisfy the condition where “the angle βo formed by the back surface S3 (light receiving surface) of the substrate 2 and the outer color filter 24o is different from the angle 3c formed by the back surface S3 (light receiving surface) of the substrate 2 and the central portion color filter 24c such that the outer color filter 24o is inclined toward the central portion of the color filter array 25 relative to the central portion color filter 24c” has been described, but other configurations may be employed. For example, a configuration where at least some (for example, 50% to 90%) of the outer color filters 24o satisfy the above-described condition, and outer color filters 24o that do not satisfy the above-described condition are present may be employed.

(3) Furthermore, in the first to fourth embodiments, the example where the central portion color filter 24c is parallel to the back surface S3 of the substrate 2 has been described, but other configurations may be employed. For example, a configuration where the central portion color filter 24c is inclined relative to the back surface S3 of the substrate 2 may be employed.

(4) Furthermore, in the first to fourth embodiments, the example where both the back surface S5 and the front surface S6 of the color filter 24 are flat surfaces has been described, but other configurations may be employed. For example, both or either of the back surface S5 and the front surface S6 of the color filter 24 may have an uneven structure.

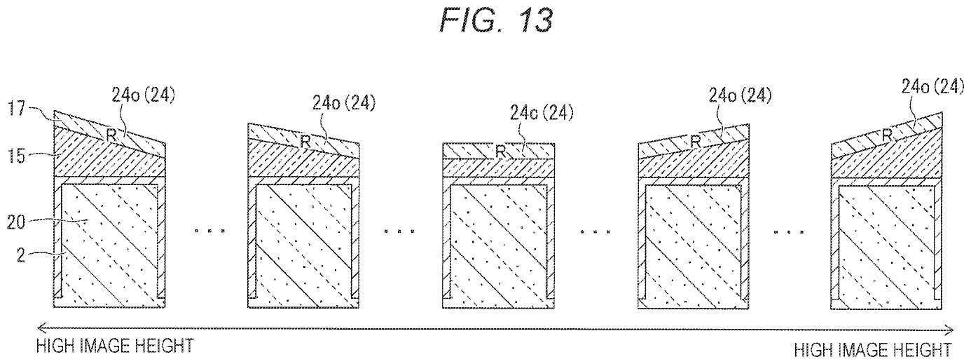

(5) Furthermore, in the first to fourth embodiments, the example where the light shielding film 14 arranged along the outer periphery of the light receiving surface of the photoelectric conversion unit 20 is formed has been described, but other configurations may be employed. For example, as depicted in FIG. 13, a configuration without the light shielding film 14 may be employed. It is possible to prevent, by removing the light shielding film 14, the incident light 21 from being blocked by the light shielding film 14 and suppress a decrease in the quantum efficiency QE due to the oblique incidence of the incident light 21 on the end portion sides (high image height sides) of the pixel region 3, which allows an increase in the sensitivity of the pixel 9.

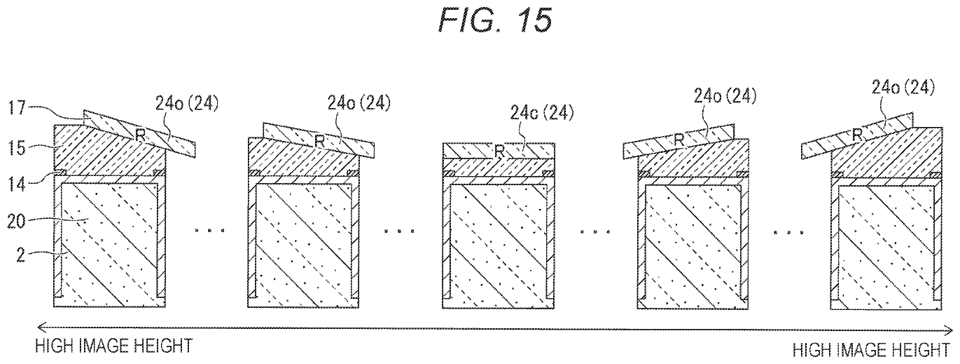

(6) Furthermore, in the first to fourth embodiments, the example where one insulating film 15 is shared by all the pixels 9 has been described, but other configurations may be employed. For example, as depicted in FIG. 15, a configuration where the insulating film 15 is provided for each pixel 9, and a waveguide wall part 33 is arranged between the insulating film 15 and the color filter 24 to form a waveguide having the insulating film 15 and the color filter 24 as a core and having the waveguide wall part 33 as a cladding may be employed. It is possible to prevent, by forming the waveguide, the incident light 21 that is obliquely incident from diffusing from the insulating film 15 on the end portion sides (high image height sides) of the pixel region 3 due to the oblique incidence of the incident light 21, which allows an increase in the sensitivity of the pixel 9. As the waveguide wall part 33, for example, a material (low refractive index material) lower in refractive index than the material of the insulating film 15 or the material of the color filter 24 may be employed.

(7) Furthermore, in the first to fourth embodiments, the example where the outer color filter 24o is arranged directly above the photoelectric conversion unit 20 has been described, but other configurations may be employed. For example, as depicted in FIG. 15, a configuration where the outer color filter 24o is arranged at a position subjected to pupil correction may be employed. That is, from the central portion toward the end portions of the pixel region 3, the central portion of the outer color filter 24o in plan view is shifted toward the central portion of the pixel region 3 relative to the center of the photoelectric conversion unit 20 corresponding to the outer color filter 24o. It is possible to suppress, with the arrangement at the position subjected to pupil correction, the occurrence of color mixing caused by the oblique incidence of the incident light 21 on the end portion sides (high image height sides) of the pixel region 3.

(8) Furthermore, the present technology is applicable to any optical detection device including not only the above-described solid-state imaging device as an image sensor but also a ranging sensor also called a time of flight (ToF) sensor that measures a distance, and the like. The ranging sensor is a sensor that emits irradiation light toward an object, detects reflected light that is the irradiation light reflected from a surface of the object, and calculates a distance to the object on the basis of a flight time from the emission of the irradiation light to reception of the reflected light. As a light receiving pixel structure of the ranging sensor, the above-described structure of the pixel 9 may be employed.

### 6. Application Example to Electronic Apparatus

The technology (present technology) according to the present disclosure may be applied to various electronic apparatuses.

FIG. 16 is a diagram depicting an example of a schematic configuration of an imaging device (video camera, digital still camera, or the like) as an electronic apparatus to which the present disclosure is applied.

As depicted in FIG. 16, an imaging device 1000 includes a lens group 1001, a solid-state imaging device 1002 (the solid-state imaging device 1 according to the first embodiment), a digital signal processor (DSP) circuit 1003, a frame memory 1004, a monitor 1005, and a memory 1006. The DSP circuit 1003, the frame memory 1004, the monitor 1005, and the memory 1006 are connected to each other over a bus line 1007.

The lens group 1001 guides incident light (image light) from a subject to the solid-state imaging device 1002 to form an image on a light receiving surface (pixel region) of the solid-state imaging device 1002.

The solid-state imaging device 1002 includes the above-described CMOS image sensor of the first embodiment. The solid-state imaging device 1002 converts the amount of the incident light formed as an image on the light receiving surface by the lens group 1001 into an electrical signal for each pixel and supplies the electrical signal to the DSP circuit 1003 as a pixel signal.

The DSP circuit 1003 performs predetermined image processing on the pixel signal supplied from the solid-state imaging device 1002. Then, the DSP circuit 1003 supplies an image signal subjected to the image processing to the frame memory 1004 for each frame to temporarily store the image signal into the frame memory 1004.

The monitor 1005 includes, for example, a panel type display device such as a liquid crystal panel or an organic electro luminescence (EL) panel. The monitor 1005 displays the image (moving image) of the subject on the basis of the pixel signal for each frame temporarily stored in the frame memory 1004.

The memory 1006 includes a DVD, a flash memory, or the like. The memory 1006 reads and records the pixel signal for each frame temporarily stored in the frame memory 1004.

Note that the electronic apparatus to which the solid-state imaging device 1 can be applied is not limited to the imaging device 1000, and the solid-state imaging device 1 can also be applied to other electronic apparatuses. Furthermore, although the configuration where the solid-state imaging device 1 according to the first embodiment is used as the solid-state imaging device 1002 has been described, other configurations may be employed. For example, a configuration where another optical detection device to which the present technology is applied, such as the solid-state imaging device 1 according to the second to fourth embodiments or the solid-state imaging device 1 according to the modification examples of the first to fourth embodiments, is used may be employed.

Note that the present technology may also have the following configurations.

(1)

An optical detection device including:
a plurality of color filters arranged in a two-dimensional array, each of the color filters transmitting light of a predetermined wavelength; and
a substrate including a plurality of photoelectric conversion units on which light passing through the color filters is incident, in which
an angle formed by a light receiving surface of the substrate and outer color filters that are the color filters located outside a central portion of the two-dimensional array is different from an angle formed by the light receiving surface of the substrate and a central portion color filter that is the color filter located at the central portion such that the outer color filters are inclined toward the central portion relative to the central portion color filter.
   (2)

The optical detection device described in (1), in which
a relative inclination angle of the outer color filter located remote from the central portion among the outer color filters relative to the central portion color filter is larger than the relative inclination angle of the outer color filter located adjacent to the central portion.
   (3)

The optical detection device described in (1) or (2), in which
for each of the outer color filters identical in spectral characteristics to each other, the relative inclination angle of the outer color filter located remote from the central portion is larger than the relative inclination angle of the outer color filter located adjacent to the central portion.
   (4)

The optical detection device described in any one of (1) to (3), in which
each of the color filters includes a multilayer film having a high refractive index layer and a low refractive index layer alternately stacked.
   (5)

The optical detection device described in any one of (1) to (3), in which
each of the color filters includes a plurality of nanostructures smaller than a wavelength of light the color filter transmits.
   (6)

The optical detection device described in any one of (1) to (3), in which
each of the color filter includes a resin material having a colorant dispersed therein.
   (7)

The optical detection device described in any one of (1) to (6), in which
the outer color filters are arranged at positions subjected to pupil correction.
   (8)

The optical detection device described in any one of (1) to (7), further including a plurality of microlenses arranged in a two-dimensional array, the microlenses being configured to concentrate incident light, in which
each of the color filters transmits light of a predetermined wavelength included in the incident light concentrated by a corresponding one of the microlenses.
   (9)

The optical detection device described in any one of (1) to (8), in which
the substrate has a central portion curved toward a side remote from the color filters.
   (10)

An electronic apparatus including an optical detection device including a plurality of color filters arranged in a two-dimensional array, each of the color filters transmitting light of a predetermined wavelength, and a substrate including a plurality of photoelectric conversion units on which light passing through the color filters is incident, in which an angle formed by a light receiving surface of the substrate and outer color filters that are the color filters located outside a central portion of the two-dimensional array is different from an angle formed by the light receiving surface of the substrate and a central portion color filter that is the color filter located at the central portion such that the outer color filters are inclined toward the central portion relative to the central portion color filter.

### REFERENCE SIGNS LIST

1 Solid-state imaging device
2 Substrate
3 Pixel region
4 Vertical drive circuit
5 Column signal processing circuit
6 Horizontal drive circuit
7 Output circuit
8 Control circuit
9 Pixel
10 Pixel drive wiring
11 Vertical signal line
12 Horizontal signal line
13 Insulating film
14 Light shielding film
15 Insulating film
16 Light receiving layer
17 Color filter layer
18 Wiring layer
19 Support substrate
20 Photoelectric conversion unit
21 Incident light
22 Pixel isolation part
23 Uneven structure
24 Color filter
24c Central portion color filter
24o Outer color filter
24r Red filter
24g Green filter
25 Color filter array
26 Interlayer insulating film
27 Wiring
28 First material film
28a First layer
28b Second layer
29 Lens base layer
30 Microlens layer
31 Microlens
32 Second material film
32c, 32o Portion of second material film
33 Waveguide wall part
50 Multilayer film
51 Nanostructure
52 Colored resin film
53 Lower mirror layer
54 Control layer
55 Upper mirror layer
56 High refractive index layer
57 Low refractive index layer
58 High refractive index layer
59 High refractive index layer
60 Low refractive index layer
61 High refractive index layer
62 Low refractive index layer
63 Guided mode resonance grating
64 Insulating layer
1000 Imaging device

1. An optical detection device comprising:
a plurality of color filters arranged in a two-dimensional array, each of the color filters transmitting light of a predetermined wavelength; and
a substrate including a plurality of photoelectric conversion units on which light passing through the color filters is incident, wherein
an angle formed by a light receiving surface of the substrate and outer color filters that are the color filters located outside a central portion of the two-dimensional array is different from an angle formed by the light receiving surface of the substrate and a central portion color filter that is the color filter located at the central portion such that the outer color filters are inclined toward the central portion relative to the central portion color filter.

2. The optical detection device according to claim 1, wherein
a relative inclination angle of the outer color filter located remote from the central portion among the outer color filters relative to the central portion color filter is larger than the relative inclination angle of the outer color filter located adjacent to the central portion.

3. The optical detection device according to claim 2, wherein
for each of the outer color filters identical in spectral characteristics to each other, the relative inclination angle of the outer color filter located remote from the central portion is larger than the relative inclination angle of the outer color filter located adjacent to the central portion.

4. The optical detection device according to claim 1, wherein
each of the color filters includes a multilayer film having a high refractive index layer and a low refractive index layer alternately stacked.

5. The optical detection device according to claim 1, wherein
each of the color filters includes a plurality of nanostructures smaller than a wavelength of light the color filter transmits.

6. The optical detection device according to claim 1, wherein
each of the color filter includes a resin material having a colorant dispersed therein.

7. The optical detection device according to claim 1, wherein
the outer color filters are arranged at positions subjected to pupil correction.

8. The optical detection device according to claim 1, further comprising a plurality of microlenses arranged in a two-dimensional array, the microlenses being configured to concentrate incident light, wherein
each of the color filters transmits light of a predetermined wavelength included in the incident light concentrated by a corresponding one of the microlenses.

9. The optical detection device according to claim 1, wherein
the substrate has a central portion curved toward a side remote from the color filters.

10. An electronic apparatus comprising an optical detection device including a plurality of color filters arranged in a two-dimensional array, each of the color filters transmitting light of a predetermined wavelength, and a substrate including a plurality of photoelectric conversion units on which light passing through the color filters is incident, wherein
an angle formed by a light receiving surface of the substrate and outer color filters that are the color filters located outside a central portion of the two-dimensional array is different from an angle formed by the light receiving surface of the substrate and a central portion color filter that is the color filter located at the central portion such that the outer color filters are inclined toward the central portion relative to the central portion color filter.
